(19) United States
(12) Patent Application Publication
(10) Pub. No.: US 2026/0162704 A1
(43) Pub. Date: Jun. 11, 2026

(54) SEMICONDUCTOR SYSTEM FOR ADJUSTING CYCLE OF REFRESH OPERATION

(71) Applicant: SK hynix Inc., Icheon-si Gyeonggi-do (KR)

(72) Inventor: Joon Yong CHOI, Icheon-si Gyeonggi-do (KR)

(73) Assignee: SK hynix Inc., Icheon-si Gyeonggi-do (KR)

(21) Appl. No.: 19/318,707

(22) Filed: Sep. 4, 2025

Related U.S. Application Data
(60) Provisional application No. 63/730,239, filed on Dec. 10, 2024.

(51) Int. Cl. G11C 11/406

(52) U.S. Cl. CPC G11C 11/40611; G11C 11/40626

(57) ABSTRACT

A semiconductor system includes a control device configured to generate input command and input data from an external command and external data, configured to generate a command and data from the input command and the input data and generate first and second refresh control signals and a memory device including a first channel and a second channel and configured to receive the command and the data and perform an internal operation based on the command and the data. The first channel performs a refresh operation in a first cycle based on the first refresh control signal. The second channel performs the refresh operation in a second cycle based on the second refresh control signal. The first channel is disposed in a thermal path that is formed when the input command and the input data are generated.

### CROSS-REFERENCE TO RELATED APPLICATION

The present application claims benefit under 35 U.S.C. § 119(e) to U.S. Provisional Application No. 63/730,239 filed on Dec. 10, 2024, the entire contents of which application is incorporated herein by reference.

### BACKGROUND

The present disclosure relates to a semiconductor system for adjusting the cycle of a refresh operation for each area based on temperature.

As technology for manufacturing a semiconductor device is developing, a packaging technology for a plurality of core chips for implementing the semiconductor device accomplishes high integration and high performance. In packaging technologies for implementing the semiconductor device, a technology relating to a three-dimensional structure in which a plurality of core chips is vertically stacked compared to a two-dimensional structure in which a plurality of core chips is flatly disposed on a printed circuit board (PCB) is variously developed. The semiconductor device having the three-dimensional structure may be implemented by stacking a plurality of core chips through a through silicon via (hereinafter referred to as a “TSV”), such as high bandwidth memory (HBM), or may be implemented by stacking a plurality of core chips through wire bonding.

### SUMMARY

In an embodiment, a semiconductor system may include a control device configured to generate input command and input data from an external command and external data, configured to generate a command and data from the input command and the input data and generate first and second refresh control signals and a memory device including a first channel and a second channel and configured to receive the command and the data and perform an internal operation based on the command and the data. The first channel performs a refresh operation in a first cycle based on the first refresh control signal. The second channel performs the refresh operation in a second cycle based on the second refresh control signal. The first channel is disposed in a thermal path that is formed when the input command and the input data are generated.

In an embodiment, a semiconductor system may include a control device configured to generate input command and input data from an external command and external data, configured to generate a command and data from the input command and the input data and generate first to third refresh control signals and a memory device including first to third channels and configured to receive the command and the data and perform an internal operation based on the command and the data. The first channel may perform a refresh operation in a first cycle based on the first refresh control signal. The second channel may perform the refresh operation in a second cycle based on the second refresh control signal. The third channel may perform the refresh operation in a third cycle based on the third refresh control signal. The first channel may be disposed in a thermal path that is formed when the input command and the input data are generated. The second channel may be disposed adjacent to the thermal path. The third channel may be disposed to be spaced apart from the thermal path with the second channel interposed between the third channel and the thermal path.

In an embodiment, a memory device may include a first channel configured to perform an internal operation by receiving a command and data that are generated from an input command and input data and configured to perform a refresh operation in a first cycle based on a first refresh control signal and a second channel configured to perform the internal operation by receiving the command and the data and configured to perform the refresh operation in a second cycle based on a second refresh control signal. The first channel may be disposed in a thermal path. The second channel may be disposed to be spaced apart from the thermal path. The thermal path may be a path along which heat that is generated when the input command and the input data are generated is transferred.

In an embodiment, a memory device may include a first channel including a first bank and a second bank and a second channel including a third bank and a fourth bank. The first bank and the second bank may perform a refresh operation in different cycles based on a first refresh control signal and a second refresh control signal. The third bank and the fourth bank may perform the refresh operation in an identical cycle based on a third refresh control signal. The first channel may be disposed in a thermal path along which heat is transferred. The second channel may be disposed to be spaced apart from the thermal path.

### BRIEF DESCRIPTION OF THE DRAWINGS

FIG. 1 is a block diagram illustrating a construction of a semiconductor system according to an embodiment of the present disclosure.

FIG. 2 is a block diagram illustrating a construction of a control device and a first memory device according to an embodiment of the present disclosure.

FIG. 3 is a block diagram illustrating a construction and connection of the control device, the first memory device, and a second memory device according to an embodiment of the present disclosure.

FIG. 4 is a diagram for describing a refresh operation of the first memory device according to an embodiment of the present disclosure.

FIG. 5 is a diagram for describing a refresh operation of the first memory device according to another embodiment of the present disclosure.

FIG. 6 is a diagram for describing a refresh operation of the first memory device according to another embodiment of the present disclosure.

FIG. 7 is a table for describing heat that is generated from a thermal path of the semiconductor system according to an embodiment of the present disclosure.

FIG. 8 is a block diagram illustrating a construction of a semiconductor system according to another embodiment of the present disclosure.

### DETAILED DESCRIPTION

In the descriptions of the following embodiments, terms such as “first” and “second,” which are used to distinguish among various components, are not limited by the components. For example, a first component may be referred to as a second component, and vice versa.

When one component is referred to as being “coupled” or “connected” to another component, it should be understood that the components may be directly coupled or connected to each other or coupled or connected to each other through another component interposed therebetween. In contrast, when one component is referred to as being “directly coupled” or “directly connected” to another component, it should be understood that the components are directly coupled or connected to each other without another component interposed therebetween.

Hereafter, the present disclosure will be described in more detail through embodiments. The embodiments are only used to exemplify the present disclosure, and the scope of the present disclosure is not limited by the embodiments.

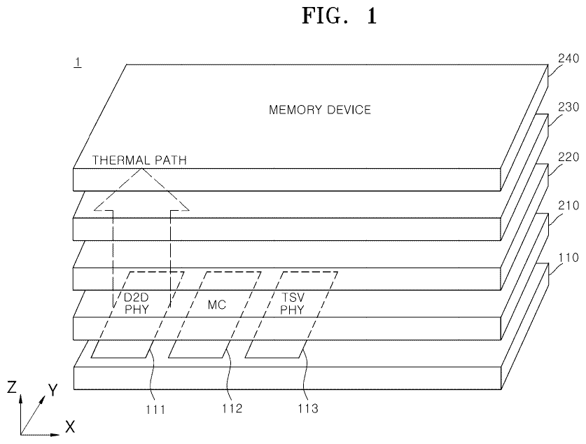

FIG. 1 is a block diagram illustrating a construction of a semiconductor system 1 according to an embodiment of the present disclosure. As illustrated in FIG. 1, the semiconductor system 1 may include a control device 110, a first memory device 210, a second memory device 220, a third memory device 230, and a fourth memory device 240.

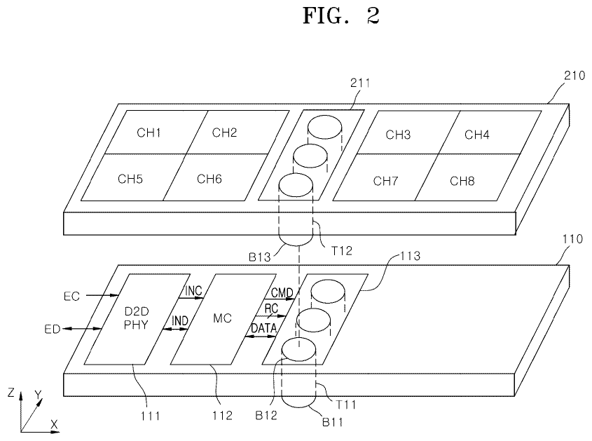

The control device 110 may generate a command (CMD in FIG. 2) and data (DATA in FIG. 2). The control device 110 may output the command and the data to the first memory device 210, the second memory device 220, the third memory device 230, and the fourth memory device 240. The control device 110 may receive the data from the first memory device 210, the second memory device 220, the third memory device 230, and the fourth memory device 240. The control device 110 may generate a plurality of refresh control signals (RC in FIG. 2). The control device 110 may output the plurality of refresh control signals to the first memory device 210, the second memory device 220, the third memory device 230, and the fourth memory device 240. The control device 110 may be implemented with a base chip that controls operations of the first memory device 210, the second memory device 220, the third memory device 230, and the fourth memory device 240.

The control device 110 may include a physical area (D2D PHY) 111, a memory controller (MC) 112, and a base TSV area (TSV PHY) 113.

The physical area 111 may generate an input command (INC in FIG. 2) and input data (IND in FIG. 2) based on a signal that is received from an external device (e.g., various devices, such as a host, a processor, and a test device). The physical area 111 may output the input command and the input data to the memory controller 112. The physical area 111 may be implemented with a physical layer PHY that is responsible for the generation, transmission, reception, and physical connection of signals and data between the external device and the control device 110.

The memory controller 112 may receive the input command and the input data from the physical area 111. Based on the input command and the input data, the memory controller 112 may output the command that controls operations of the first memory device 210, the second memory device 220, the third memory device 230, and the fourth memory device 240 and may output the data. The memory controller 112 may generate the plurality of refresh control signals that controls refresh operations of the first memory device 210, the second memory device 220, the third memory device 230, and the fourth memory device 240. The refresh operation may be set as an operation that stores the data DATA again within a retention time, that is, the time for which the data DATA stored in the first memory device 210, the second memory device 220, the third memory device 230, and the fourth memory device 240 are stably maintained by sensing and amplifying the data DATA.

The base TSV area 113 may include a plurality of TSVs. The base TSV area 113 may receive the command and the data from the memory controller 112. The base TSV area 113 may output the command and the data to the first memory device 210, the second memory device 220, the third memory device 230, and the fourth memory device 240 through the plurality of TSVs. The base TSV area 113 may receive the plurality of refresh control signals from the memory controller 112. The base TSV area 113 may output the plurality of refresh control signals to the first memory device 210, the second memory device 220, the third memory device 230, and the fourth memory device 240 through the plurality of TSVs.

When the physical area 111 generates the input command and the input data, a thermal path may be formed. The thermal path may be set as a path along which heat that is generated when the input command and the input data are generated is transferred.

The first memory device 210 may include a plurality of channels (CH1 to CH8 in FIG. 2). The plurality of channels included in the first memory device 210 may perform an internal operation by receiving the command and the data. The plurality of channels included in the first memory device 210 may store the data after the start of a write operation based on the command. The plurality of channels included in the first memory device 210 may output the data stored after the start of a read operation based on the command. The plurality of channels included in the first memory device 210 may perform a refresh operation by receiving the plurality of refresh control signals. The cycle of the refresh operation performed by the plurality of channels included in the first memory device 210 may be adjusted based on the plurality of refresh control signals. The cycle of a refresh operation performed by a channel included in the thermal path, among the plurality of channels included in the first memory device 210, may be the shortest.

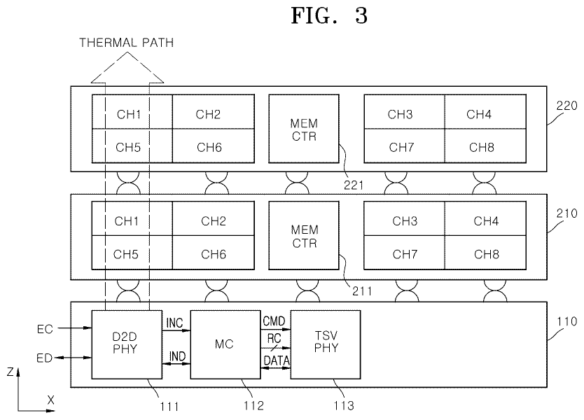

The second memory device 220 may include a plurality of channels (CH1 to CH8 in FIG. 3). The plurality of channels included in the second memory device 220 may perform an internal operation by receiving the command and the data. The plurality of channels included in the second memory device 220 may store the data after the start of a write operation based on the command. The plurality of channels included in the second memory device 220 may output the data stored after the start of a read operation based on the command. The plurality of channels included in the second memory device 220 may perform a refresh operation by receiving the plurality of refresh control signals (RC in FIG. 3). The cycle of the refresh operation performed by the plurality of channels included in the second memory device 220 may be adjusted based on the plurality of refresh control signals. The cycle of a refresh operation performed by a channel included in a thermal path, among the plurality of channels included in the second memory device 220, may be the shortest.

The third memory device 230 may include a plurality of channels. The plurality of channels included in the third memory device 230 may perform an internal operation by receiving the command and the data. The plurality of channels included in the third memory device 230 may store the data after the start of a write operation based on the command. The plurality of channels included in the third memory device 230 may output the data stored after the start of a read operation based on the command. The plurality of channels included in the third memory device 230 may perform a refresh operation by receiving the plurality of refresh control signals. The cycle of the refresh operation performed by the plurality of channels included in the third memory device 230 may be adjusted based on the plurality of refresh control signals. The cycle of a refresh operation performed by a channel included in a thermal path, among the plurality of channels included in the third memory device 230, may be the shortest.

The fourth memory device 240 may include a plurality of channels. The plurality of channels included in the fourth memory device 240 may perform an internal operation by receiving the command and the data. The plurality of channels included in the fourth memory device 240 may store the data after the start of a write operation based on the command. The plurality of channels included in the fourth memory device 240 may output the data stored after the start of a read operation based on the command. The plurality of channels included in the fourth memory device 240 may perform a refresh operation by receiving the plurality of refresh control signals. The cycle of the refresh operation performed by the plurality of channels included in the fourth memory device 240 may be adjusted based on the plurality of refresh control signals. The cycle of a refresh operation performed by a channel included in a thermal path, among the plurality of channels included in the fourth memory device 240, may be the shortest.

The control device 110, the first memory device 210, the second memory device 220, the third memory device 230, and the fourth memory device 240 may be horizontally implemented on an X-Y plane. The first memory device 210 may be vertically stacked on the control device 110 in a Z-direction. The second memory device 220 may be vertically stacked on the first memory device 210 in the Z-direction. The third memory device 230 may be vertically stacked on the second memory device 220 in the Z-direction. The fourth memory device 240 may be vertically stacked on the third memory device 230 in the Z-direction.

A thermal path may be vertically formed in the Z-direction from the physical area 111 included in the control device 110. Heat that is generated from the thermal path may be spread to the first memory device 210, the second memory device 220, the third memory device 230, and the fourth memory device 240.

The first memory device 210, the second memory device 220, the third memory device 230, and the fourth memory device 240 may each be implemented with a core chip or a semiconductor device that stores data and outputs stored data.

The semiconductor system 1, illustrated in FIG. 1, has been illustrated so that the four first to fourth memory devices 210, 220, 230, and 240 are stacked on the control device 110; however, various numbers of memory devices, such as 8, 12, and 16, may be stacked on the control device 110.

As described above, the semiconductor system 1 according to an embodiment of the present disclosure can secure the reliability of data by performing a refresh operation on an area that is included in a memory device and that is included in a thermal path that is formed from the control device 110 in a short cycle. The reliability of data stored in a channel can be secured by adjusting the cycle of a refresh operation differently based on a thermal path that is formed from the control device 110 and a difference between the locations of channels included in a memory device.

FIG. 2 is a block diagram illustrating a construction of the control device 110 and first memory device 210 of the semiconductor system 1 according to an embodiment of the present disclosure. As illustrated in FIG. 2, the control device 110 may include the physical area 111, the memory controller 112, and the base TSV area 113.

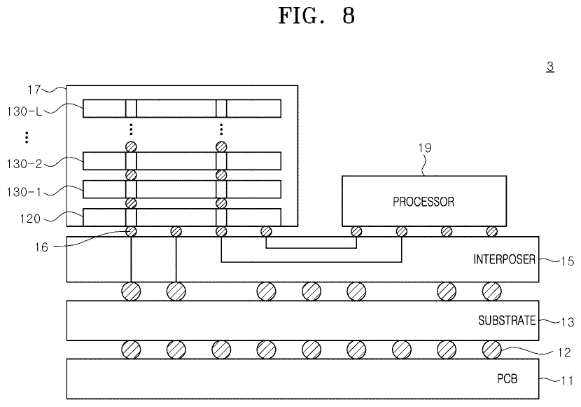

The physical area 111 may generate the input command INC by receiving an external command EC from an external device (e.g., a processor in FIG. 8). The physical area 111 may generate the input command INC by buffering or decoding the external command EC. The external command EC and the input command INC each have been illustrated as one signal, but may each include a plurality of bits. The physical area 111 may generate the input data IND by receiving external data ED from the external device (e.g., the processor in FIG. 8). The physical area 111 may generate the external data ED by receiving the input data IND from the memory controller 112. The physical area 111 may output the external data ED to the external device. The external data ED and the input data IND each have been illustrated as one signal but may include a plurality of bits. The physical area 111 may be disposed in the thermal path.

The memory controller 112 may receive the input command INC and the input data IND from the physical area 111. Based on the input command INC and the input data IND, the memory controller 112 may output the command CMD that controls operations of the first memory device 210, the second memory device 220, the third memory device 230, and the fourth memory device 240 and the data DATA. The memory controller 112 may generate the plurality of refresh control signals RC that controls refresh operations of the first memory device 210, the second memory device 220, the third memory device 230, and the fourth memory device 240. The plurality of refresh control signals RC may each be set as a signal, the generation cycle of which is adjusted in order to adjust the cycle of a refresh operation. The memory controller 112 may generate the input data IND by receiving the data DATA from the base TSV area 113. The memory controller 112 may output the input data IND to the physical area 111.

The base TSV area 113 may include a plurality of TSVs. The base TSV area 113 may receive the command CMD and the data DATA from the memory controller 112. The base TSV area 113 may output the command CMD and the data DATA to the first memory device 210, the second memory device 220, the third memory device 230, and the fourth memory device 240 through the plurality of TSVs. The base TSV area 113 may receive the plurality of refresh control signals RC from the memory controller 112. The base TSV area 113 may output the plurality of refresh control signals RC to the first memory device 210, the second memory device 220, the third memory device 230, and the fourth memory device 240 through the plurality of TSVs. The base TSV area 113 may receive the data DATA from the first memory device 210, the second memory device 220, the third memory device 230, and the fourth memory device 240 through the plurality of TSVs and may output the data DATA to the memory controller 112.

The base TSV area 113 may include a TSV T11 that is connected between a micro bump B11 and a micro bump B12. The micro bump B11 may be set as a micro bump that is connected to the wire of an external device (e.g., an interposer in FIG. 8). The micro bump B12 may be set as a micro bump that is connected to a micro bump B13 connected to the first memory device 210. The base TSV area 113 has been illustrated as including three TSVs; however, the base TSV area 113 may include a plurality of TSVs connected to a plurality of micro bumps.

The physical area 111, memory controller 112, and base TSV area 113 of the control device 110 may be disposed in the X-direction.

The first memory device 210 may include a memory control circuit (MEM CTR) 211 and first to eighth channels CH1 to CH8.

The memory control circuit 211 may include a plurality of TSVs. The memory control circuit 211 may receive the command CMD and the data DATA from the base TSV area 113. The memory control circuit 211 may output the command CMD and the data DATA that are received through the plurality of TSVs to the first to eighth channels CH1 to CH8. The memory control circuit 211 may receive the plurality of refresh control signals RC from the base TSV area 113. The memory control circuit 211 may output the plurality of refresh control signals RC that is received through the plurality of TSVs to the first to eighth channels CH1 to CH8. The memory control circuit 211 may receive the data DATA from the first to eighth channels CH1 to CH8 and may output the data DATA to the base TSV area 113.

The memory control circuit 211 may include a TSV T12 that is connected to the micro bump B13. The micro bump B13 may be set as a micro bump that is connected to the micro bump B12. The memory control circuit 211 has been illustrated as including three TSVs; however, the memory control circuit 211 may include a plurality of TSVs that is connected to a plurality of micro bumps.

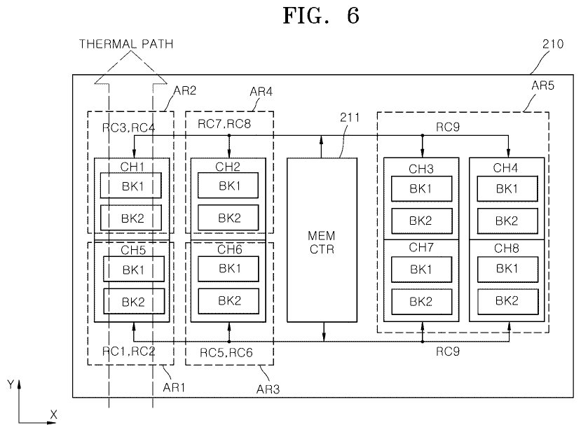

The first to eighth channels CH1 to CH8 may each receive the command CMD and the data DATA by independently performing an internal operation. The first to eighth channels CH1 to CH8 may each store the data DATA after the start of a write operation of the internal operation based on the command CMD. The first to eighth channels CH1 to CH8 may each output the data DATA after the start of a read operation of the internal operation based on the command CMD. The cycle of a refresh operation performed by each of the first to eighth channels CH1 to CH8 may be adjusted based on each of the plurality of refresh control signals RC. For example, when the refresh control signal RC that is input to the first channel CH1 is twice as fast as the refresh control signal RC that is input to the second channel CH2, the first channel CH1 may perform a refresh operation in a cycle that is twice as fast as the refresh operation of the second channel CH2. The first to eighth channels CH1 to CH8 may each include a plurality of banks (BK1 and BK2 in FIG. 6).

The memory control circuit 211 and first to eighth channels CH1 to CH8 of the first memory device 210 may be disposed in the X-direction. The first memory device 210, illustrated in FIG. 2, may be electrically connected to a plurality of micro bumps, such as the micro bumps B12 and B13, and may be stacked on the control device 110 in the Z-direction.

The second memory device 220, the third memory device 230, and the fourth memory device 240, illustrated in FIG. 1, are vertically stacked on the first memory device 210 in the Z-direction and are implemented with the same components as the first memory device 210 and perform the same operation as the first memory device 210, and thus, detailed descriptions thereof are omitted.

FIG. 3 is a block diagram illustrating a construction and connection of the control device 110, the first memory device 210, and the second memory device 220 according to an embodiment of the present disclosure.

The physical area 111 of the control device 110 may generate the input command INC by receiving the external command EC from an external device (e.g., the processor in FIG. 8). The physical area 111 of the control device 110 may generate the input command INC by buffering or decoding the external command EC. The physical area 111 of the control device 110 may generate the input data IND by receiving the external data ED from the external device. Heat may be generated when the physical area 111 of the control device 110 generates the input command INC and the input data IND by receiving the external command EC and the external data ED. In this case, the generated heat may be vertically spread in the Z-direction, thus forming a thermal path.

Based on the input command INC and the input data IND, the memory controller 112 of the control device 110 may output the command CMD that controls operations of the first memory device 210 and the second memory device 220 and may output the data DATA. The memory controller 112 of the control device 110 may output the plurality of refresh control signals RC that controls refresh operations of the first memory device 210 and the second memory device 220.

The base TSV area 113 of the control device 110 may receive the command CMD and the data DATA from the memory controller 112. The base TSV area 113 of the control device 110 may output the command CMD and the data DATA to the first memory device 210 and the second memory device 220 through a plurality of TSVs. The base TSV area 113 of the control device 110 may receive the plurality of refresh control signals RC from the memory controller 112. The base TSV area 113 of the control device 110 may output the plurality of refresh control signals RC to the first memory device 210 and the second memory device 220 through the plurality of TSVs.

The memory control circuit 211 of the first memory device 210 may receive the command CMD and the data DATA from the base TSV area 113. The memory control circuit 211 of the first memory device 210 may output the received command CMD and data DATA to the first to eighth channels CH1 to CH8. The memory control circuit 211 of the first memory device 210 may receive the plurality of refresh control signals RC from the base TSV area 113. The memory control circuit 211 of the first memory device 210 may output the plurality of refresh control signals RC to the first to eighth channels CH1 to CH8. In this case, the first channel CH1 and the fifth channel CH5 that are included in the thermal path may perform a refresh operation in a first cycle by receiving the refresh control signal RC that is generated in the first cycle, that is, the fastest cycle. The second channel CH2 and the sixth channel CH6 that are disposed adjacent to the thermal path may perform a refresh operation in a second cycle by receiving the refresh control signal RC that is generated in the second cycle. The third channel CH3, the fourth channel CH4, the seventh channel CH7, and the eighth channel CH8, against which heat that is generated from the thermal path is blocked through the second channel CH2 and the sixth channel CH6, may perform a refresh operation in a third cycle by receiving the refresh control signal RC that is generated in the third cycle. The first cycle may be shorter than the second cycle. The second cycle may be shorter than the third cycle. The first cycle may be half of the second cycle. The second cycle may be half of the third cycle. Accordingly, the first cycle may be a quarter of the third cycle. The first cycle, the second cycle, and the third cycle may be variously set according to an embodiment. The first memory device 210 vertically stacked in the Z-direction of the control device 110 through the plurality of micro bumps.

A memory control circuit (MEM CTR) 221 of the second memory device 220 may receive the command CMD and the data DATA from the base TSV area 113. The memory control circuit 221 of the second memory device 220 may output the received command CMD and data DATA to the first to eighth channels CH1 to CH8. The memory control circuit 221 of the second memory device 220 may receive the plurality of refresh control signals RC from the base TSV area 113. The memory control circuit 221 of the second memory device 220 may output the plurality of refresh control signals RC to the first to eighth channels CH1 to CH8. In this case, the first channel CH1 and the fifth channel CH5 that are included in the thermal path may perform a refresh operation in the first cycle by receiving the refresh control signal RC that is generated in the first cycle, that is, the fastest cycle. The second channel CH2 and the sixth channel CH6 that are disposed adjacent to the thermal path may perform a refresh operation in the second cycle by receiving the refresh control signal RC that is generated in the second cycle. The third channel CH3, the fourth channel CH4, the seventh channel CH7, and the eighth channel CH8, against which heat that is generated from the thermal path is blocked through the second channel CH2 and the sixth channel CH6, may perform a refresh operation in the third cycle by receiving the refresh control signal RC that is generated in the third cycle. The second memory device 220 may be vertically stacked in the Z-direction of the first memory device 210 through the plurality of micro bumps.

As described above, the semiconductor system 1 can secure the reliability of data stored in a channel by performing a refresh operation on the channel that is included in a memory device and that is included in a thermal path that is formed from the control device 110 in a short cycle. The semiconductor system 1 can secure the reliability of data stored in a channel by adjusting the cycle of a refresh operation differently based on a thermal path that is formed from the control device 110 and a difference between the locations of channels included in a memory device.

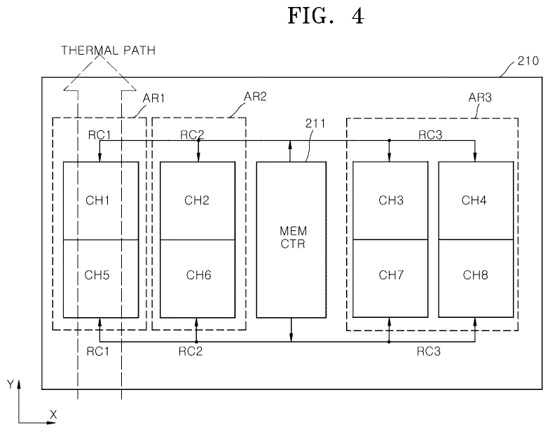

FIG. 4 is a diagram for describing a refresh operation of the first memory device 210 according to an embodiment of the present disclosure. A refresh operation of the first memory device 210 is described with reference to FIG. 4. In this case, a case in which the heat of a thermal path that is formed from the control device 110 is identically spread to the first channel CH1 and the fifth channel CH5 is described as follows as an example.

The memory control circuit 211 of the first memory device 210 may receive a first refresh control signal RC1, a second refresh control signal RC2, and a third refresh control signal RC3 from the base TSV area 113. The first refresh control signal RC1 may be generated in the first cycle and received by the corresponding channels. The second refresh control signal RC2 may be generated in the second cycle and received by the corresponding channels. The third refresh control signal RC3 may be generated in the third cycle and received by the corresponding channels. The first cycle may be shorter than the second cycle. The second cycle may be shorter than the third cycle. The first cycle may be half of the second cycle. The second cycle may be half of the third cycle. The first cycle, the second cycle, and the third cycle may be variously adjusted depending on heat that is generated from a thermal path.

The first channel CH1 and the fifth channel CH5 may be disposed in a first area AR1 included in the thermal path. The memory control circuit 211 of the first memory device 210 may output the first refresh control signal RC1 that is generated in the first cycle to the first channel CH1 and the fifth channel CH5. The first channel CH1 and the fifth channel CH5 may perform a refresh operation in the first cycle based on the first refresh control signal RC1.

The second channel CH2 and the sixth channel CH6 may be disposed in a second area AR2 adjacent to the thermal path. The memory control circuit 211 of the first memory device 210 may output the second refresh control signal RC2 that is generated in the second cycle to the second channel CH2 and the sixth channel CH6. The second channel CH2 and the sixth channel CH6 may perform a refresh operation in the second cycle based on the second refresh control signal RC2.

The third channel CH3, the fourth channel CH4, the seventh channel CH7, and the eighth channel CH8 may be disposed in a third area AR3 that is spaced apart from the first area AR1 with the second area AR2 interposed therebetween. The memory control circuit 211 of the first memory device 210 may output the third refresh control signal RC3 that is generated in the third cycle to the third channel CH3, the fourth channel CH4, the seventh channel CH7, and the eighth channel CH8. The third channel CH3, the fourth channel CH4, the seventh channel CH7, and the eighth channel CH8 may perform a refresh operation in the third cycle based on the third refresh control signal RC3.

The first channel CH1 and fifth channel CH5 that are disposed in the first area AR1 included in the thermal path may perform the refresh operation in the first cycle, that is, the fastest cycle, because the retention time for which the data DATA are stably maintained according to the heat that is generated from the thermal path is the shortest time.

The second channel CH2 and sixth channel CH6 of the second area AR2 that are adjacent to the thermal path may perform a refresh operation in the second cycle, which is slower than the first cycle, because the retention time for which the data DATA are stably maintained according to the heat that is generated from the thermal path is increased compared to the first area AR1.

The third channel CH3, fourth channel CH4, seventh channel CH7, and eighth channel CH8 of the third area AR3, which are spaced apart from the first area AR1 with the second area AR2 interposed therebetween, may perform a refresh operation in the third cycle, which is slower than the second cycle, because the retention time for which the data DATA are stably maintained according to the heat that is generated from the thermal path is increased compared to the second area AR2.

The second memory device 220, the third memory device 230, and the fourth memory device 240 each may perform the same refresh operation as the first memory device 210, and thus, detailed descriptions thereof are omitted.

As described above, the semiconductor system 1 can secure the reliability of data stored in a channel by performing a refresh operation on the channel that is included in a memory device and that is included in a thermal path that is formed from the control device 110 in a short cycle. The semiconductor system 1 can secure the reliability of data stored in a channel by adjusting the cycle of a refresh operation differently based on a thermal path that is formed from the control device 110 and a difference between the locations of channels included in a memory device.

The memory control circuit 211 and first to eighth channels CH1 to CH8 of the first memory device 210, illustrated in FIG. 4, may be horizontally disposed on an X-Y plane.

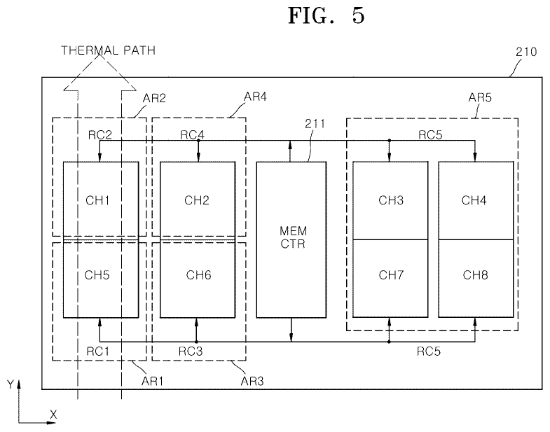

FIG. 5 is a diagram for describing a refresh operation of the first memory device 210 according to another embodiment of the present disclosure. A refresh operation of the first memory device 210 is described with reference to FIG. 5. In this case, a case in which the heat of a thermal path that is formed from the control device 110 is spread to the fifth channel CH5 at a high temperature rather than the first channel CH1 is described as follows as an example.

The memory control circuit 211 of the first memory device 210 may receive a first refresh control signal RC1, a second refresh control signal RC2, a third refresh control signal RC3, a fourth refresh control signal RC4, and a fifth refresh control signal RC5 from the base TSV area 113. The first refresh control signal RC1 may be generated in a first cycle and received by the corresponding channel. The second refresh control signal RC2 may be generated in a second cycle and received by the corresponding channel. The third refresh control signal RC3 may be generated in a third cycle and received by the corresponding channel. The fourth refresh control signal RC4 may be generated in a fourth cycle and received by the corresponding channel. The fifth refresh control signal RC5 may be generated in a fifth cycle and received by the corresponding channels.

The first cycle may be shorter than the second cycle. The second cycle may be shorter than the third cycle. The third cycle may be shorter than the fourth cycle. The fourth cycle may be shorter than the fifth cycle. The first cycle may be half of the second cycle. The second cycle may be half of the third cycle. The third cycle may be half the fourth cycle. The fourth cycle may be half of the fifth cycle. The first cycle, the second cycle, the third cycle, the fourth cycle, and the fifth cycle may be variously adjusted depending on heat that is generated from the thermal path.

The fifth channel CH5 may be disposed in a first area AR1 included in the thermal path. The first channel CH1 may be disposed in a second area AR2 included in the thermal path. The memory control circuit 211 of the first memory device 210 may output the first refresh control signal RC1 that is generated in the first cycle to the fifth channel CH5 and may output the second refresh control signal RC2 that is generated in the second cycle to the first channel CH1. The fifth channel CH5 may perform a refresh operation in the first cycle based on the first refresh control signal RC1. The first channel CH1 may perform a refresh operation in the second cycle based on the second refresh control signal RC2.

The sixth channel CH6 may be disposed in a third area AR3 adjacent to the thermal path. The second channel CH2 may be disposed in a fourth area AR4 adjacent to the thermal path. The memory control circuit 211 of the first memory device 210 may output the third refresh control signal RC3 that is generated in the third cycle to the sixth channel CH6 and may output the fourth refresh control signal RC4 that is generated in the fourth cycle to the second channel CH2. The sixth channel CH6 may perform a refresh operation in the third cycle based on the third refresh control signal RC3. The second channel CH2 may perform a refresh operation in the fourth cycle based on the fourth refresh control signal RC4.

The third channel CH3, the fourth channel CH4, the seventh channel CH7, and the eighth channel CH8 may be disposed in a fifth area AR5 that is spaced apart from the first area AR1 with the second area AR2 with the third area AR3 and the fourth area AR4 interposed therebetween. The memory control circuit 211 of the first memory device 210 may output the fifth refresh control signal RC5 that is generated in the fifth cycle to the third channel CH3, the fourth channel CH4, the seventh channel CH7, and the eighth channel CH8. The third channel CH3, the fourth channel CH4, the seventh channel CH7, and the eighth channel CH8 may perform a refresh operation in the fifth cycle based on the fifth refresh control signal RC5.

The fifth channel CH5 of the first area AR1 included in the thermal path may perform a refresh operation in the first cycle, that is, the fastest cycle, because the retention time for which the data DATA are stably maintained according to the heat that is generated from the thermal path is the shortest time. The first channel CH1 of the second area AR2 included in the thermal path may perform a refresh operation in the second cycle, which is slower than the first cycle, because the retention time for which the data DATA are stably maintained according to the heat that is generated from the thermal path is increased compared to the fifth channel CH5.

The sixth channel CH6 of the third area AR3 adjacent to the thermal path may perform a refresh operation in the third cycle, which is slower than the second cycle, because the retention time for which the data DATA are stably maintained according to the heat that is generated from the thermal path is increased compared to the second area AR2. The second channel CH2 of the fourth area AR4 adjacent to the thermal path may perform a refresh operation in the fourth cycle, which is slower than the third cycle, because the retention time for which the data DATA are stably maintained according to the heat that is generated from the thermal path is increased compared to the third area AR3.

The third channel CH3, fourth channel CH4, seventh channel CH7, and eighth channel CH8 of the fifth area AR5 that is spaced apart from the first area AR1 and the second area AR2 with the third area AR3 and the fourth area AR4 interposed therebetween may perform a refresh operation in the fifth cycle, which is slower than the fourth cycle, because the retention time for which the data DATA are stably maintained according to the heat that is generated from the thermal path is increased compared to the fourth area AR4.

The second memory device 220, the third memory device 230, and the fourth memory device 240 may each perform the same refresh operation as the first memory device 210, and thus, detailed descriptions thereof are omitted.

The memory control circuit 211 and first to eighth channels CH1 to CH8 of the first memory device 210 illustrated in FIG. 5 may be horizontally disposed on a plane of an X axis and a Y axis.

As described above, the semiconductor system 1 can secure the reliability of data stored in a channel by performing a refresh operation on the channel that is included in a memory device and that is included in a thermal path that is formed from the control device 110 in a short cycle. The semiconductor system 1 can secure the reliability of data stored in a channel by adjusting the cycle of a refresh operation differently based on a thermal path that is formed from the control device 110 and a difference between the locations of channels included in a memory device.

FIG. 6 is a diagram for describing a refresh operation of the first memory device 210 according to another embodiment of the present disclosure. A refresh operation of the first memory device 210 is described with reference to FIG. 6. In this case, a case in which the heat of a thermal path that is formed from the control device 110 is spread to the fifth channel CH5 at a high temperature rather than the first channel CH1 and is spread to second banks BK2 of the first channel CH1 and the fifth channel CH5 at a high temperature rather than first banks BK1 of the first channel CH1 and the fifth channel CH5 is described as follows as an example.

The memory control circuit 211 of the first memory device 210 may receive a first refresh control signal RC1, a second refresh control signal RC2, a third refresh control signal RC3, a fourth refresh control signal RC4, a fifth refresh control signal RC5, a sixth refresh control signal RC6, a seventh refresh control signal RC7, an eighth refresh control signal RC8, and a ninth refresh control signal RC9 from the base TSV area 113. The first refresh control signal RC1 may be generated in a first cycle and received by the corresponding channel. The second refresh control signal RC2 may be generated in a second cycle and received by the corresponding channel. The third refresh control signal RC3 may be generated in a third cycle and received by the corresponding channel. The fourth refresh control signal RC4 may be generated in a fourth cycle and received by the corresponding channel. The fifth refresh control signal RC5 may be generated in a fifth cycle and received. The sixth refresh control signal RC6 may be generated in a sixth cycle and received. The seventh refresh control signal RC7 may be generated in a seventh cycle and received by the corresponding channel. The eighth refresh control signal RC8 is generated in an eighth cycle and received by the corresponding channel. The ninth refresh control signal RC9 may be generated in a ninth cycle and received by the corresponding channels.

The first cycle may be shorter than the second cycle. The second cycle may be shorter than the third cycle. The third cycle may be shorter than the fourth cycle. The fourth cycle may be shorter than the fifth cycle. The fifth cycle may be shorter than the sixth cycle. The sixth cycle may be shorter than the seventh cycle. The seventh cycle may be shorter than the eighth cycle. The eighth cycle may be shorter than the ninth cycle.

The first cycle may be half of the second cycle. The second cycle may be half of the third cycle. The third cycle may be half of the fourth cycle. The fourth cycle may be half of the fifth cycle. The fifth cycle may be half of the sixth cycle. The sixth cycle may be half of the seventh cycle. The seventh cycle may be half of the eighth cycle. The eighth cycle may be half of the ninth cycle.

The first cycle, the second cycle, the third cycle, the fourth cycle, the fifth cycle, the sixth cycle, the seventh cycle, the eighth cycle and the ninth cycle may be variously adjusted depending on heat that is generated from the thermal path.

The fifth channel CH5 may be disposed in a first area AR1 included in the thermal path. The first channel CH1 may be disposed in a second area AR2 included in the thermal path.

The memory control circuit 211 of the first memory device 210 may output the first refresh control signal RC1 that is generated in the first cycle to the second bank BK2 of the fifth channel CH5 and may output the second refresh control signal RC2 that is generated in the second cycle to the first bank BK1 of the fifth channel CH5. The second bank BK2 of the fifth channel CH5 may perform a refresh operation in the first cycle based on the first refresh control signal RC1. The first bank BK1 of the fifth channel CH5 may perform a refresh operation in the second cycle based on the second refresh control signal RC2.

The memory control circuit 211 of the first memory device 210 may output the third refresh control signal RC3 that is generated in the third cycle to the second bank BK2 of the first channel CH1 and may output the fourth refresh control signal RC4 that is generated in the fourth cycle to the first bank BK1 of the first channel CH1. The second bank BK2 of the first channel CH1 may perform a refresh operation in the third cycle based on the third refresh control signal RC3. The first bank BK1 of the first channel CH1 may perform a refresh operation in the fourth cycle based on the fourth refresh control signal RC4.

The sixth channel CH6 may be disposed in a third area AR3 adjacent to the thermal path. The second channel CH2 may be disposed in a fourth area AR4 adjacent to the thermal path.

The memory control circuit 211 of the first memory device 210 may output the fifth refresh control signal RC5 that is generated in the fifth cycle to a second bank BK2 of the sixth channel CH6 and may output the sixth refresh control signal RC6 that is generated in the sixth cycle to a first bank BK1 of the sixth channel CH6. The second bank BK2 of the sixth channel CH6 may perform a refresh operation in the fifth cycle based on the fifth refresh control signal RC5. The first bank BK1 of the sixth channel CH6 may perform a refresh operation in the sixth cycle based on the sixth refresh control signal RC6.

The memory control circuit 211 of the first memory device 210 may output the seventh refresh control signal RC7 that is generated in the seventh cycle to a second bank BK2 of the second channel CH2 and may output the eighth refresh control signal RC8 that is generated in the eighth cycle to a first bank BK1 of the second channel CH2. The second bank BK2 of the second channel CH2 may perform a refresh operation in the seventh cycle based on the seventh refresh control signal RC7. The first bank BK1 of the second channel CH2 may perform a refresh operation in the eighth cycle based on the eighth refresh control signal RC8.

The third channel CH3, the fourth channel CH4, the seventh channel CH7, and the eighth channel CH8 may be disposed in a fifth area AR5 that is spaced apart from the first area AR1 and the second area AR2 with the third area AR3 and the fourth area AR4 interposed therebetween.

The memory control circuit 211 of the first memory device 210 may output the ninth refresh control signal RC9 that is generated in the ninth cycle to the third channel CH3, the fourth channel CH4, the seventh channel CH7, and the eighth channel CH8. The third channel CH3, the fourth channel CH4, the seventh channel CH7, and the eighth channel CH8 may perform a refresh operation in the ninth cycle based on the ninth refresh control signal RC9.

The second bank BK2 of the fifth channel CH5 included in the thermal path may perform a refresh operation in the first cycle, that is, the fastest cycle, because the retention time for which the data DATA are stably maintained according to the heat that is generated from the thermal path is the shortest time. The first bank BK1 of the fifth channel CH5 included in the thermal path may perform a refresh operation in the second cycle, which is slower than the first cycle, because the retention time for which the data DATA are stably maintained according to the heat that is generated from the thermal path is increased compared to the second bank BK2 of the fifth channel CH5.

The second bank BK2 of the first channel CH1 included in the thermal path may perform a refresh operation in the third cycle because the retention time for which the data DATA are stably maintained according to the heat that is generated from the thermal path is increased compared to the first bank BK1 of the fifth channel CH5. The first bank BK1 of the first channel CH1 included in the thermal path may perform a refresh operation in the fourth cycle, which is slower than the third cycle, because the retention time for which the data DATA are stably maintained according to the heat that is generated from the thermal path is increased compared to the second bank BK2 of the first channel CH1.

The second bank BK2 of the sixth channel CH6 of the third area AR3 adjacent to the thermal path may perform a refresh operation in the fifth cycle, which is slower than the fourth cycle, because the retention time for which the data DATA are stably maintained according to the heat that is generated from the thermal path is increased compared to the first bank BK1 of the first channel CH1. The first bank BK1 of the sixth channel CH6 of the third area AR3 may perform a refresh operation in the sixth cycle, which is slower than the fifth cycle, because the retention time for which the data DATA are stably maintained according to the heat that is generated from the thermal path is increased compared to the second bank BK2 of the sixth channel CH6.

The second bank BK2 of the second channel CH2 of the third area AR3 adjacent to the thermal path may perform a refresh operation in the seventh cycle, which is slower than the sixth cycle, because the retention time for which the data DATA are stably maintained according to the heat that is generated from the thermal path is increased compared to the first bank BK1 of the sixth channel CH6. The first bank BK1 of the second channel CH2 of the third area AR3 adjacent to the thermal path may perform a refresh operation in the eighth cycle slower than the seventh cycle because the retention time for which the data DATA are stably maintained according to the heat that is generated from the thermal path is increased compared to the second bank BK2 of the second channel CH2.

The third channel CH3, fourth channel CH4, seventh channel CH7, and eighth channel CH8 of the fifth area AR5 that is spaced apart from the first area AR1 and the second area AR2 with the third area AR3 and the fourth area AR4 interposed therebetween may perform a refresh operation in the ninth cycle, which is slower than the eighth cycle, because the retention time for which the data DATA are stably maintained according to the heat that is generated from the thermal path is increased compared to the first bank BK1 of the second channel CH2.

### The Memory Control Circuit 211 and First to Eighth Channels CH1 to CH8 of the first memory device 210, illustrated in FIG. 6, may be horizontally disposed on an X-Y plane.

The second memory device 220, the third memory device 230, and the fourth memory device 240 may each perform the same refresh operation as the first memory device 210, and thus, detailed descriptions thereof are omitted.

As described above, the semiconductor system 1 can secure the reliability of data stored in a channel by performing a refresh operation on the channel that is included in a memory device and that is included in a thermal path that is formed from the control device 110 in a short cycle. The semiconductor system 1 can secure the reliability of data stored in a channel by adjusting the cycle of a refresh operation differently depending on a thermal path that is formed from the control device 110 and a difference between the locations of channels included in a memory device.

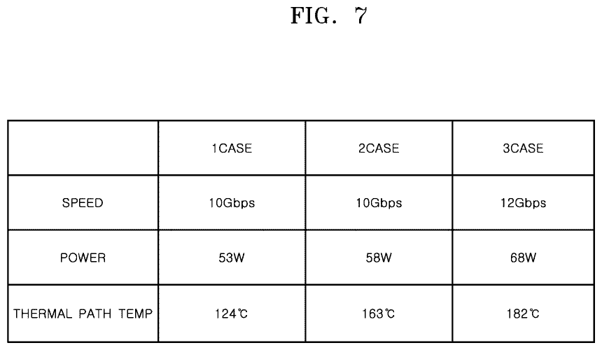

FIG. 7 is a table for describing heat that is generated from a thermal path of the semiconductor system 1 according to an embodiment of the present disclosure.

A first case 1CASE is a case in which the operating speed SPEED of the semiconductor system 1 is 10 Gbps and consumption power POWER is 53 W. In the first case 1CASE, the temperature of the thermal path THERMAL PATH TEMP is 124° C.

A second case 2CASE is a case in which the operating speed SPEED of the semiconductor system 1 is 10 Gbps and consumption power POWER is 58 W. In the second case 2CASE, the temperature of a thermal path THERMAL PATH TEMP is 163° C.

A third case 3CASE is a case in which the operating speed SPEED of the semiconductor system 1 is 12 Gbps and consumption power POWER is 68 W. In the third case 3CASE, the temperature of a thermal path THERMAL PATH TEMP is 182° C.

As illustrated in the table, it may be seen that the temperature of the thermal path THERMAL PATH TEMP increases from 124° C. to 163° C. when the operating speed SPEED of the semiconductor system 1 is identical at 10 Gbps and the consumption power POWER is increased from 53 W to 58 W. That is, it is possible to secure the reliability of data only when a refresh operation is performed in a shorter cycle as the temperature of the thermal path THERMAL PATH TEMP increases.

Furthermore, as illustrated in the table, it may be seen that the temperature of the thermal path THERMAL PATH TEMP increases from 163° C. to 182° C. when the same operating speed SPEED of the semiconductor system 1 is increased from 10 Gbps to 12 Gbps and the consumption power POWER is increased from 58 W to 68W. That is, it is possible to secure the reliability of data only when a refresh operation is performed in a shorter cycle as the temperature of the thermal path THERMAL PATH TEMP increases.

FIG. 8 is a block diagram illustrating a construction of a semiconductor system 3 according to another embodiment of the present disclosure. As illustrated in FIG. 8, the semiconductor system 3 may include a PCB 11, a substrate 13, the interposer 15, an HBM device 17, and a processor 19.

The PCB 11 connects several electronic components in order to form an electronic circuit (not illustrated). A copper layer, a solder mask, and a silkscreen may be formed on the PCB 11. A circuit path that transmits a signal or power may be formed in the copper layer. The solder mask prevents damage to the circuit and protects a specific region in which components may be soldered. Furthermore, the silkscreen indicates a position or information of an electronic component in the form of characters or symbols printed on a surface of the PCB 11.

The substrate 13 is formed over the PCB 11 through bump pads (e.g., 12) and may mechanically support the interposer 15, the HBM device 17, and the processor 19. The substrate 13 may be used as an insulator as a material, that is, a physical base for the PCB 11, in general. The material of the substrate 13 includes FR4, that is, an insulator made of glass fiber and epoxy resin, ceramics which can withstand a high temperature and is commonly used in a high frequency circuit or a high temperature environment due to its thermal conductivity, and polyimide which is used as a base material for a flexible PCB due to its flexible characteristic.

The interposer 15 is formed over the substrate 13 through bump pads and may include wires that connect electronic components (e.g., the HBM device 17 and the processor 19) with unmatched form factors or pin arrangements. The interposer 15 may convert signals in different interfaces.

The HBM device 17 may be formed over the interposer 15 through micro bump pads (e.g., 16). Under the control of the processor 19, the HBM device 17 may store data applied by the processor 19 or may output data stored in the HBM device 17 to the processor 19. The HBM device 17 may include a base chip 120 and a plurality of core chips 130-1 to 130-L. The plurality of core chips 130-1 to 130-L may be stacked on or over the base chip 120 through micro bump pads. The base chip 120 and the plurality of core chips 130-1 to 130-L may be vertically connected through TSVs. The base chip 120 may generate the command CMD by receiving the external command EC from the processor 19 through the wire of the interposer 15. The base chip 120 may generate the data DATA by receiving the external data ED from the processor 19. The base chip 120 may output the data DATA to the processor 19 through the wire of the interposer 15. The base chip 120 may output the command CMD and the data DATA to the plurality of core chips 130-1 to 130-L through the TSVs. The base chip 120 may generate the plurality of refresh control signals RC, the generation cycle of each of which is adjusted in order to adjust the cycles of refresh operations of the plurality of core chips 130-1 to 130-L. The base chip 120 may output the plurality of refresh control signals RC to the plurality of core chips 130-1 to 130-L through the TSVs.

When the base chip 120 generates the input command INC and the input data IND, a thermal path may be formed. The thermal path may be set as a path along which heat generated when the input command INC and the input data IND are generated is transferred. The thermal path may be formed vertically from the base chip 120.

The base chip 120 may be implemented with the control device 110 as illustrated in FIG. 1.

Each of the plurality of core chips 130-1 to 130-L may include a plurality of channel areas that independently operates. Each of the plurality of channel areas may be assigned a channel that independently operates and may receive or transmit the data DATA. Each of the plurality of channel areas may include a core region and may receive or transmit data. Some channels included in the plurality of channel areas included in each of the plurality of core chips 130-1 to 130-L may be included and disposed in a thermal path. Some channels included in the plurality of channel areas included in each of the plurality of core chips 130-1 to 130-L may be disposed adjacent to a thermal path. Some channels included in the plurality of channel areas included in each of the plurality of core chips 130-1 to 130-L may be is disposed to be spaced apart from a thermal path. Channels included in a thermal path may perform a refresh operation in the fastest cycle based on the plurality of refresh control signals RC that is generated in the fastest cycle. Channels that are disposed adjacent to a thermal path may perform a refresh operation in a slower cycle than channels included in the thermal path. Channels that are disposed to be spaced apart from a thermal path may perform a refresh operation in a slower cycle than channels disposed adjacent to the thermal path.

The number L of core chips 130-1 to 130-L may be 4, 8, 12, or 16. For example, when each of the core chips 130-1 to 130-12 has eight channels, each of the core chips 130-1 to 130-4, the core chips 130-5 to 130-8, and the core chips 130-9 to 130-12 may include 32 channel areas and may transmit and receive data to and from the processor 19 in a rank unit including 32 channels.

The core chips 130-1 to 130-L may each be implemented with the memory devices 210, 220, 230, and 240 as illustrated in FIG. 1.

The HBM device 17 can secure the reliability of data stored in a channel by performing a refresh operation on the channel that is included in the plurality of core chips 130-1 to 130-L and that is included in a thermal path that is formed from the base chip 120 in a short cycle. The HBM device 17 can secure the reliability of data stored in a channel by adjusting the cycle of a refresh operation differently based on a thermal path that is formed from the base chip 120 and a difference between the locations of channels included in the plurality of core chips 130-1 to 130-L.

The processor 19 may control an operation of the base chip 120 through a wire formed within the interposer 15. The processor 19 may control the base chip 120 so that a command (not illustrated) that controls operations of the core chips 121-1 to 121-L and signals (not illustrated) are output to the core chips 121-1 to 121-L that perform operations.

What is claimed is:

1. A semiconductor system comprising:
a control device configured to:
generate input command and input data from an external command and external data; and
generate a command and data from the input command and the input data and generate first and second refresh control signals; and
a memory device comprising a first channel and a second channel and configured to receive the command and the data and perform an internal operation based on the command and the data,
wherein the first channel performs a refresh operation in a first cycle based on the first refresh control signal,
wherein the second channel performs the refresh operation in a second cycle based on the second refresh control signal, and
wherein the first channel is disposed in a thermal path that is formed when the input command and the input data are generated.

2. The semiconductor system of claim 1, wherein the first cycle is shorter than the second cycle.

3. The semiconductor system of claim 1,
wherein the first cycle is set as a cycle that is ½N of the second cycle, and
wherein the N is set as an integer greater than 0.

4. The semiconductor system of claim 1,
wherein the thermal path is set as a path along which heat that is generated when the input command and the input data are generated is transferred, and
wherein the thermal path is formed in a vertical direction from the control device.

5. The semiconductor system of claim 1, wherein the control device comprises:
a physical area configured to generate the input command and the input data by receiving the external command and the external data from an external device;
a memory controller configured to receive the input command and the input data from the physical area and configured to output the command and the data in order to control the internal operation of the memory device based on the input command and the input data and output the first refresh control signal and the second refresh control signal; and
a base TSV area configured to receive the command, the data, the first refresh control signal, and the second refresh control signal from the memory controller and configured to output the command, the data, the first refresh control signal, and the second refresh control signal to the memory device.

6. The semiconductor system of claim 5, wherein the physical area is disposed in the thermal path.

7. The semiconductor system of claim 1, wherein the memory device comprises:
a memory control circuit electrically connected to the control device, configured to:
receive the command, the data, and the first refresh control signal and output the command, the data, and the first refresh control signal to the first channel, and
receive the command, the data, and the second refresh control signal and output the command, the data, and the second refresh control signal to the second channel;
the first channel configured to perform the internal operation based on the command and the data and configured to perform the refresh operation in the first cycle based on the first refresh control signal; and
the second channel configured to perform the internal operation based on the command and the data and configured to perform the refresh operation in the second cycle based on the second refresh control signal.

8. The semiconductor system of claim 7,
wherein the first channel is disposed in a first area included in the thermal path, and
wherein the second channel is disposed in a second area adjacent to the thermal path.

9. A semiconductor system comprising:
a control device configured to:
generate input command and input data from an external command and external data; and
generate a command and data from the input command and the input data and generate first to third refresh control signals; and
a memory device comprising first to third channels and configured to receive the command and the data and perform an internal operation based on the command and the data,
wherein the first channel performs a refresh operation in a first cycle based on the first refresh control signal,
wherein the second channel performs the refresh operation in a second cycle based on the second refresh control signal,
wherein the third channel performs the refresh operation in a third cycle based on the third refresh control signal,
wherein the first channel is disposed in a thermal path that is formed when the input command and the input data are generated,
wherein the second channel is disposed adjacent to the thermal path, and
wherein the third channel is disposed to be spaced apart from the thermal path with the second channel interposed between the third channel and the thermal path.

10. The semiconductor system of claim 9, wherein the first cycle is shorter than the second cycle, and wherein the second cycle is shorter than the third cycle.

11. The semiconductor system of claim 9,
wherein the first cycle is set as a cycle that is ½N of the second cycle,
wherein the second cycle is set as a cycle that is 1/N of the third cycle, and
wherein the N is set as an integer greater than 0.

12. The semiconductor system of claim 9,
wherein the thermal path is set as a path along which heat that is generated when the input command and the input data are generated is transferred, and
wherein the thermal path is formed in a vertical direction from the control device.

13. The semiconductor system of claim 9, wherein the control device comprises:
a physical area configured to generate the input command and the input data by receiving the external command and the external data from an external device;
a memory controller configured to receive the input command and the input data from the physical area and configured to output the command and the data in order to control the internal operation of the memory device based on the input command and the input data and output the first to third refresh control signals; and
a base TSV area configured to receive the command, the data, and the first to third refresh control signals from the memory controller and configured to output the command, the data, the first to third refresh control signals to the memory device.

14. The semiconductor system of claim 13, wherein the physical area is disposed in the thermal path.

15. The semiconductor system of claim 9, wherein the memory device comprises:
a memory control circuit electrically connected to the control device, configured to:
receive the command, the data, and the first refresh control signal and output the command, the data, and the first refresh control signal to the first channel,
receive the command, the data, and the second refresh control signal and output the command, the data, and the second refresh control signal to the second channel, and
receive the command, the data, and the third refresh control signal and output the command, the data, and the third refresh control signal to the third channel;
the first channel configured to perform the internal operation based on the command and the data and configured to perform the refresh operation in the first cycle based on the first refresh control signal;
the second channel configured to perform the internal operation based on the command and the data and configured to perform the refresh operation in the second cycle based on the second refresh control signal; and
the third channel configured to perform the internal operation based on the command and the data and configured to perform the refresh operation in the third cycle based on the third refresh control signal.

16. The semiconductor system of claim 15,
wherein the first channel is disposed in a first area included in the thermal path,
wherein the second channel is disposed in a second area adjacent to the thermal path, and
wherein the third channel is disposed in a third area spaced apart from the first area with the second area interposed between the third area and the first area.

17. A memory device comprising:
a first channel configured to perform an internal operation by receiving a command and data that are generated from an input command and input data and configured to perform a refresh operation in a first cycle based on a first refresh control signal; and
a second channel configured to perform the internal operation by receiving the command and the data and configured to perform the refresh operation in a second cycle based on a second refresh control signal,
wherein the first channel is disposed in a thermal path,
wherein the second channel is disposed to be spaced apart from the thermal path, and
wherein the thermal path is a path along which heat that is generated when the input command and the input data are generated is transferred.

18. The semiconductor system of claim 17, wherein the first cycle is shorter than the second cycle.

19. The semiconductor system of claim 17,
wherein the first cycle is set as a cycle that is ½N of the second cycle, and
wherein the N is set as an integer greater than 0.

20. The semiconductor system of claim 17, wherein the thermal path is set as a path along which the heat generated when the input command and the input data that perform the internal operation of the first channel and the second channel are generated is transferred.

21. A memory device comprising:
a first channel comprising a first bank and a second bank; and
a second channel comprising a third bank and a fourth bank,
wherein the first bank and the second bank perform a refresh operation in different cycles based on a first refresh control signal and a second refresh control signal,
wherein the third bank and the fourth bank perform the refresh operation in an identical cycle based on a third refresh control signal,
wherein the first channel is disposed in a thermal path along which heat is transferred, and
wherein the second channel is disposed to be spaced apart from the thermal path.

22. The memory device of claim 21,
wherein the thermal path is set as a path along which the heat generated when an input command and input data that perform an internal operation of the first channel and the second channel are generated is transferred, and
wherein the thermal path is formed in a direction from the first bank to the second bank.

23. The memory device of claim 21,
wherein the first bank performs the refresh operation in a first cycle based on the first refresh control signal, and
wherein the second bank performs the refresh operation in a second cycle based on the second refresh control signal.

24. The memory device of claim 23, wherein the first cycle is shorter than the second cycle.

25. The memory device of claim 23,
wherein the first cycle is set as a cycle that is ½N of the second cycle, and
wherein the N is set as an integer greater than 0.

26. The memory device of claim 25,
wherein the third bank performs the refresh operation in a third cycle based on the third refresh control signal, and
wherein the fourth bank performs the refresh operation in the third cycle based on the third refresh control signal.

27. The memory device of claim 26, wherein the third cycle is set as a cycle that is ½N of the second cycle.
